(19) United States
(12) Patent Application Publication
(10) Pub. No.: US 2008/0318033 A1
(43) Pub. Date: Dec. 25, 2008

(54) Coated Substrate with a Temporary Protective Layer and Method for Production Thereof

(75) Inventors: Walter Zultzke, Maintal (DE); Markus Fuhr, Eppstein (DE); Manfred Viet, Alzenau (DE); Klaus Nauenburg, Hanau (DE)

Correspondence Address: CANTOR COLBURN, LLP, 20 Church Street, 22nd Floor, Hartford, CT, 06103, US

(73) Assignee: LEYBOLD OPTICS GMBH, ALZENAU (DE)

(21) Appl. No.: 11/909,540

(22) PCT Filed: Mar. 22, 2006
(86) PCT No.: PCT/EP2006/002629

§ 371 Date: May 28, 2008

(30) Foreign Application Priority Data
Mar. 23, 2005 (DE) 10 2005 014 031.9

(51) Int. Cl. B32B 5/00; B05D 5/00; C23C 16/48; C23C 16/513; C09D 1/00; B05D 3/04; B05D 3/00

(52) U.S. Cl. 428/336; 427/154; 427/585; 427/576; 427/535; 427/551; 106/286.8

(57) ABSTRACT

The invention relates to a method for production of a coated substrate, whereby at least one functional layer is deposited on the substrate from the vapor phase by means of chemical or physical deposition of a coating material and a temporary protective layer is applied to the functional layer by means of evaporation of a salt, in particular, an alkali metal halide. The invention further relates to a coated substrate with at least one functional layer and a temporary protective layer applied to the functional layer, which comprises a salt, in particular, an alkali metal halide, preferably a salt-like alkali metal halide and more particularly sodium chloride.

The invention relates to a method for production of coated substrates with a temporary protective layer, whereby at least one functional layer is deposited on at least one side of the substrate by means of a CVD or PVD process, and a temporary protective layer is applied to at least one coated side of the substrate, also a substrate that is coated with a temporary protective layer.

Temporary protective layers, i.e., removable layers for protecting the surfaces of sensitive substrates, particularly for protection against mechanical damage or chemical attacks, are known from many different branches of industry. These protective layers serve to protect the surfaces during further treatment and/or during transportation and/or during storage of the substrates until the time of their intended use.

Typical protective layers consist of polymers or waxes. Removal of these types of substances takes place by means of organic or inorganic solutions, for example acidic or alkaline solutions, hydrocarbonates or alcohol solutions. These solutions have the shortcoming, however, that they are incompatible with and corrosive to many substrate materials and/or coating materials. Particularly for transparent substrates of glass or plastic with a large variety of functional layers, temporary protective layers of this type are unsuitable.

Patent document WO 01/02496 discloses a protective layer of carbon, which is formed by means of application of a liquid polymeric layer composition to the substrate or coated substrate and subsequent hardening or drying of the layer composition. This protective layer is used particularly as mechanical protection of glass substrates with a multitude of functional layers. The protective layer can be rinsed off by means of a suitable liquid, especially water, or burned off. In many practical applications, the very thin functional layers are deposited on the substrates in a vacuum chamber by means of CVD (chemical vapor deposition) or PVD (physical vapor deposition.) The subsequent application of the protective layer according to WO 01/02496 requires significant time and expenditure, as the substrates must be removed from the vacuum chamber and treated in an additional treatment station. This method is particularly unsuitable if the substrates are already provided with a protective layer on the coated front, for example for purposes of coating the back, and must again be transported into a vacuum chamber for further coating.

This is the case, for example, when coating optical substrates, more particularly lenses. These are provided on both sides with optical functional layers and/or scratch-protection layers and a [sic] final hydrophobic and/or oleophobic clean-coat layers, by means of reactive processes in the vacuum. The clean-coat layer is sensitive, especially to the action of reactive components. In patent document WO 03/057641 A1, the hydrophobic and/or oleophobic coating that already exists on one side of the substrate is coated for protection purposes in the vacuum chamber with a temporary thin protective layer of a metal fluoride, more particularly of MgF₂, LaF₃ or CeF₃, prior to the subsequent treatment of the other side of the substrate. These metal fluorides can be also vapor-deposited in the vacuum chamber. The temporary protective layer can subsequently be wiped off. This, again, involves significant time and expenditure. Moreover, when the protective layer is wiped off, a very sensitive hydrophobic and/or oleophobic clean-coat layer that is located underneath may be damaged in the process.

The invention therefore has as its object to provide a simple and economical method for the production of coated substrates with an easily removable temporary protective layer, also a coated substrate with an easily removable protective layer.

This object can be met with a method according to claim 1 and with a coated substrate according to claim 25. Additional advantageous embodiments are specified in the respective subclaims.

In the inventive method for production of a coated substrate, at least one functional layer is applied to the substrate by means of chemical or physical deposition of a coating material from the vapor phase, and a temporary protective layer is deposited on the functional layer by means of evaporation of a salt that is easily soluble in water or in a polar organic or protic organic solvent, and/or by means of evaporation of a compound that forms a salt-like layer that is easily soluble in water, in a polar organic or protic organic solvent.

Easily soluble in water or in a polar organic or protic organic solvent within the meaning of this invention refers to a solubility of more than 1 g per 100 cm³ of solvent at room temperature.

In a particularly advantageous embodiment of the method, a salt-like alkali metal halide, especially sodium chloride, is evaporated for deposition of the temporary protective layer.

Alkali metal halides are chemical compounds of the halogens, i.e., of the elements of the 7^{th} main group (fluorine, chlorine, bromine, iodine, astatine) with alkali metals, i.e., elements of the 1^{st} main group (lithium, sodium, potassium, rubidium, cesium, francium.)

The protective layer is applied only temporarily, i.e., for a transient period of time during which the layers that are located underneath must be protected, and is easily removed without negatively impacting the surface that is located underneath it. Removal of the salt-like alkali metal halide protective layer is accomplished preferably by means of rinsing with a polar liquid, especially with water.

In an advantageous embodiment of the invention, both the functional layer, or functional layers, as well as the protective layer are deposited by means of evaporation using a thermally heated resistance evaporator or an electron-beam evaporator, so that the coating process can take place in a vacuum chamber.

An optically active layer that is composed of a plurality of individual layers, a so-called multilayer coating, and/or a scratch-protection coating, which comprise metals or metal compounds, more particularly metal oxides, is applied as the first functional layer.

In an additional embodiment, a second, hydrophobic and/or oleophobic functional layer is applied as so-called clean-coat layer with a highly smoothing action to the first functional layer and/or to the substrate. This second functional layer is preferably deposited by means of evaporation of organic silicon compounds or fluorinated hydrocarbon compounds. The organic silicon compounds or fluorinated hydrocarbon compounds preferably comprise at least partially perfluorinated carbon atoms or carbon chains. The organic silicon compounds or fluorinated hydrocarbon compounds may additionally have saturated aliphatic carbon atoms or carbon chains and/or oxygen-containing and nitrogen-containing functional groups.

In order to improve the adhesive property of the functional layers on the substrate, it is advantageous in this context if the substrate is treated with a plasma beam or ion beam prior to the deposition of a functional layer and/or if the first functional layer is deposited by means of a plasma-assisted or ion-assisted process in order to affect layer properties.

In an additional embodiment of the inventive method, the substrate is treated and/or coated on both sides, in such a way that the front of the substrate is treated in a first step with a plasma beam or ion beam and/or coated with at least one functional layer, and subsequently coated with the temporary protective layer. When treating and/or coating the back of the substrate in a second step, the front of the substrate, which was coated first, is then protected by the temporary protective layer. This is advantageous particularly if the treatment and/or coating of the back of the substrate takes place under the action of ions or a plasma.

The thickness of the protective layer is dependent in this context upon the penetration depth of the charge carriers into the layer, and it is preferably selected such that the surfaces or functional layers located underneath cannot be affected

The inventive method may be carried out using any desired vacuum coating apparatus that is equipped with a suitable evaporator for vapor-deposition of the protective layer.

The inventive coated substrate, which preferably has been produced with the inventive method, comprises at least one functional layer, and deposited on the functional layer one temporary protective layer comprising a salt or salt-like compound that are easily soluble in a polar or protic organic solvent.

In a particularly advantageous embodiment, the temporary protective layer comprises an alkali metal halide, preferably sodium chloride. A temporary protective layer of sodium chloride can be easily applied by means of evaporation and easily rinsed off with water without negatively affecting very sensitive functional layers located underneath.

The protective layer preferably has a thickness of 5 nm to 100 nm, more particularly of 10 nm.

The functional layers may preferably be implemented in the form of optically active functional layers, and/or scratch-protection layers, and/or hydrophobic and/or oleophobic functional layers, and may be applied either to one side, or to a front and back of the substrate. Likewise, the temporary protective layer may be applied to one side, or also to a coated front and coated or uncoated back of the substrate.

The invention will be further described below based on an exemplary embodiment, with drawings depicting the following:

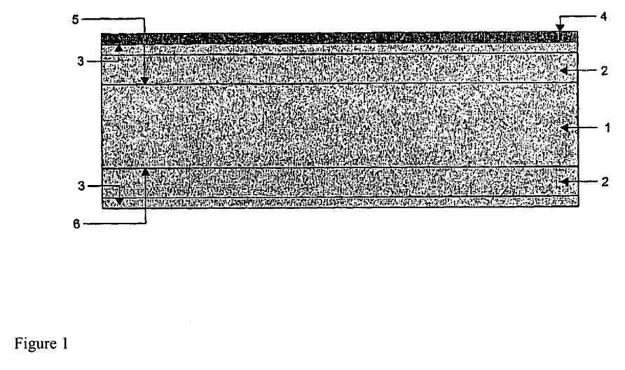

FIG. 1 a coated substrate

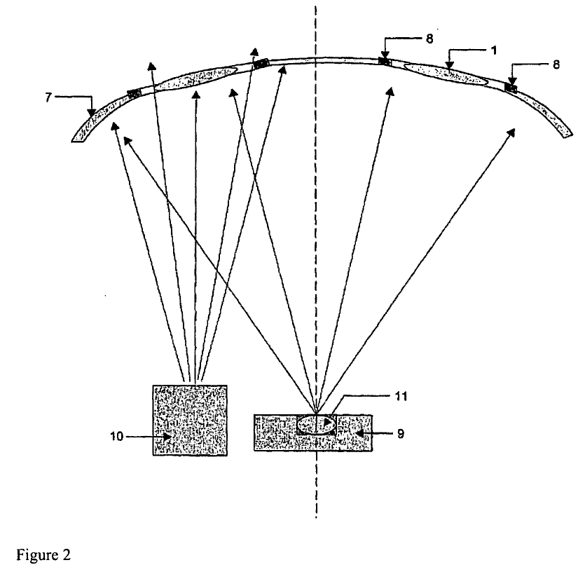

FIG. 2 a schematic illustration of a coating arrangement

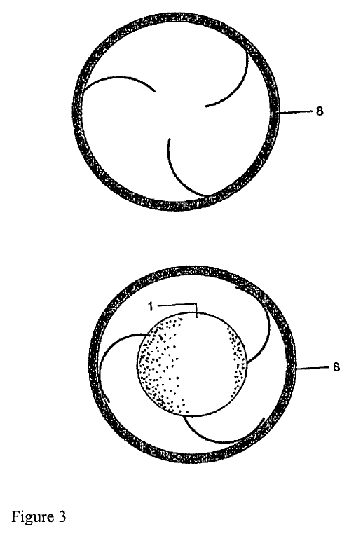

FIG. 3 a holder for the substrate

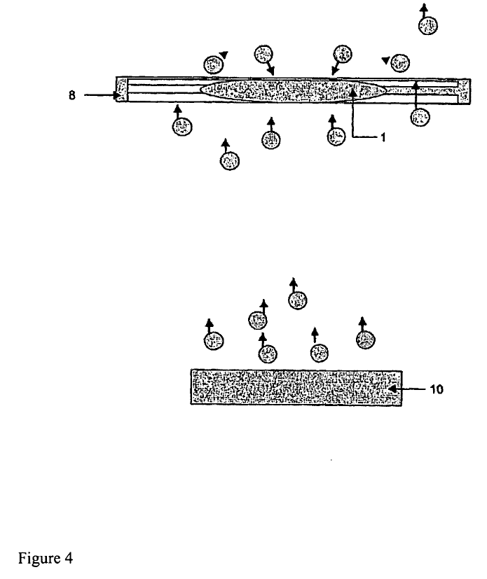

FIG. 4 the movement of charge carriers

In ophthalmics, for example for the production of eyeglass lenses, substrates consisting of glass or plastic must be coated on both sides with anti-reflective layers and clean-coat layers.

For the production of the eyeglass lenses, a plurality of substrates 1 are arranged for coating as shown in FIG. 2 in a vacuum chamber (not depicted) on a dome-shaped substrate holder 7, which is rotatable about a shaft. In the vacuum chamber, an ion/plasma source 10 is arranged below the substrate holder 7. It provides for irradiation of the substrate surface with a plasma/ion beam prior to the coating process to create improved adhesion, and for irradiation of the growing layer during the coating process to affect layer properties. Additionally, an electron beam evaporator 9, which evaporates the respective required coating material 11 for the layer being applied, is disposed in the vacuum chamber below the substrate holder 7. Provided for holding the substrates 1 on the substrate holder 7 are the substrate spring rings 8 that are shown in FIGS. 3 and 4. Between the supported substrate 1 and the substrate spring ring 8, a gap is created, which permits unimpeded access of the charge carriers to the back of the substrate 1 during coating or treatment of the front of a substrate 1 with plasma beams or ion beams.

In a first process step the fronts 5 of the substrates 1 are coated in an evacuated vacuum chamber. The substrates 1, which are supported in the substrate holder 7, are pretreated for this purpose by means of an ion beam. As the first functional layer 2, an anti-reflective coating consisting of a plurality of individual layers, for example titanium oxides, zirconium oxides, tantalum oxides, aluminum oxides, silicon oxides, are vapor-deposited by means of an electron-beam evaporator 9. Coating of the substrates 1 with the first functional layer 2 consisting of a plurality of individual layers, takes place with the aid of an ion beam. Switching of the coating materials 11 for generation of the various layers is accomplished by means of a rotating crucible. As the second and last functional layer 3, a hydrophobic clean-coat layer is vapor-deposited on the first functional layer 2 by means of the electron-beam evaporator 9.

If the substrate 1 were already turned over at this time and coated from its back 6 as described above, the very sensitive clean-coat layer would be destroyed by the above-described action of charge carriers, which is shown in FIG. 4.

To prevent this from occurring, an additional layer in the form of the protective layer 4 is vapor-deposited in the first process step during coating process of the front 5 of the substrate 1. The temporary protective layer 4 is produced by evaporation of pure sodium chloride by means of the electron-beam evaporator 9.

After venting of the vacuum chamber, the substrates 1 are turned over on the substrate holder 7 for coating the back 6. In a second process step, the backs 6 of the substrates 1 are then coated in the newly evacuated vacuum chamber, as described above, with a first and second functional layer 2, 3.

FIG. 1 shows the schematic depiction of a substrate 1 that has been coated as described above. The first functional layer 2 that was applied to the front 5 and back 6 of the substrate 1 is an anti-reflective coating consisting of a plurality of individual layers of, e.g., titanium oxides, zirconium oxides, tantalum oxides, aluminum oxides, silicon oxides, and has a thickness of 100-500 nm. The second and last functional layer 3, which is also deposited on the front 5 and back 6 of the substrate 1 is a clean-coat layer and has a thickness of 25 nm. The protective layer of sodium chloride that is vapor-deposited only on the front 5 of the substrate 1 has a thickness of 10 nm and is suitable to prevent the penetration of charge carriers down to the clean-coat layer while the back 6 of the substrate 1 is being coated.

After coating of the back 6 of the substrate 1, the protective layer 4 is removed. The protective layer 4 of sodium chloride is not stable in the long term and does not have good adhesion to the clean-coat layer underneath and is therefore very easily removable by rinsing with water, without damaging the clean-coat layer. After removal of the protective layer 4, the hydrophobic behavior of the clean-coat layer is fully restored.

The edges of substrates 1 that have been coated with a clean-coat layer must be treated further for the production of eyeglass lenses. Since the clean-coat layer creates a very high degree of surface smoothness, the adhesive pads used for substrate-edge machining no longer adhere properly. The substrate 1 frequently slips about its axis during the process of grinding its periphery, and can then no longer be used.

If, in this case, the substrate 1 is provided during the coating process with a temporary protective layer 4 on both sides, the adhesive pads for substrate-edge machining can again adhere well. After machining of the substrate edges, the temporary protective layer 4 on both sides can again be removed as described above.

### LIST OF REFERENCE NUMERALS

1 substrate
2 first functional layer
3 second functional layer
4 protective layer
5 front
6 back
7 substrate holder
8 substrate spring ring
9 electron-beam evaporator
10 ion/plasma source
11 coating material

What is claimed is:

1. A method for production of a coated substrate (1), whereby at least one functional layer (2, 3) is deposited on the substrate (1) by means of chemical or physical deposition of a coating material from the vapor phase, and a temporary protective layer (4) is applied to at least one functional layer (2, 3), characterized in that the temporary protective layer (4) is applied by means of evaporation of a salt that is easily soluble in water or in a polar or protic organic solvent and/or by means of evaporation of a compound forming a salt-like layer that is easily soluble in water or in a polar or protic organic solvent.

2. A method according to claim 1, characterized in that, for deposition of the temporary protective layer (4), a compound comprising a halide is evaporated.

3. A method according to claim 2, characterized in that, for deposition of the temporary protective layer (4), a compound comprising an alkali metal halide is evaporated.

4. A method according to claim 3, characterized in that, for deposition of the temporary protective layer (4), sodium chloride is evaporated.

5. A method according to claim 1, characterized in that, for deposition of the temporary protective layer (4), a salt of an inorganic acid is evaporated.

6. A method according to claim 5, characterized in that, for deposition of the temporary protective layer (4), a nitrite compound or nitrate compound comprising at least one metal of the first, second or third main group (Li, Na, K, Rb, Cs, Fr, Be, Mg, Ca, Sr, Ba, Ra, B, Al, Sc, Y, La) or of the third subgroup (Ga, In, Tl) or comprising a lantanoid, is evaporated.

7. A method according to claim 5, characterized in that for deposition of the temporary protective layer (4), a sulfate compound comprising at least one metal of the third main group or subgroup (B, Al, Sc, Y, La, Ga, In, Tl) or comprising a lantanoid, is evaporated.

8. A method according to claim 5, characterized in that, for deposition of the temporary protective layer (4), a sulfide compound comprising at least one metal of the first main group (Li, Na, K, Rb, Cs, Fr) is evaporated.

9. A method according to claim 5, characterized in that, for deposition of the temporary protective layer (4), a salt-like azide comprising at least one metal of the first or second main group (Li, Na, K, Rb, Cs, Fr, Be, Mg, Ca, Sr, Ba, Ra) is evaporated.

10. A method according to claim 5, characterized in that, for deposition of the temporary protective layer (4), a salt-like (iso)cyanide, (iso)cyanate, (iso)fulminate, or (iso)thiocyanate is evaporated.

11. A method according to claim 1, characterized in that, for deposition of the temporary protective layer (4), a salt-like compound comprising an alkali metal oxide is evaporated.

12. A method according to claim 1, characterized in that, for deposition of the temporary protective layer (4), an organic or carbon-comprising alkali metal compound is evaporated, preferably under addition of oxygen.

13. A method according to any of the above claims, characterized in that the temporary protective layer (4) is applied by means of evaporation using a thermally heated resistance evaporator or an electron-beam evaporator (9).

14. A method according to any of the above claims, characterized in that the temporary protective layer (4) is applied with a thickness of 5 nm to 100 nm, more particularly of 10 nm.

15. A method according to any of the above claims, characterized in that at least a first functional layer (2) comprising at least one metal or at least one metal compound is applied.

16. A method according to claim 15, characterized in that a multilayer coating of different metals or metal compounds is applied as the first functional layer (2).

17. A method according to claim 15 or 16, characterized in that the first functional layer (2) is applied by means of evaporation of a coating material (11) using a thermally heated resistance evaporator or an electron-beam evaporator (9).

18. A method according to any of claims 15 through 17, characterized in that the first functional layer (2) is applied by means of a plasma-beam-assisted or ion-beam-assisted process.

19. A method according to any of the above claims, characterized in that the substrate (1) is treated with a plasma beam or ion beam prior to the application of a first functional layer (2).

20. A method according to any of the above claims, characterized in that a second, hydrophobic and/or oleophobic functional layer (3) is applied to the substrate (1) or to the first functional layer (2).

21. A method according to claim 20, characterized in that a second, hydrophobic and/or oleophobic functional layer (3) comprising at least one silicon-organic compound having at least partially perfluorinated carbon atoms or carbon chains is applied to the substrate (1) or the first functional layer (2).

22. A method according to any of claims 20 or 21, characterized in that the second, hydrophobic and/or oleophobic functional layer (3) is applied by means of evaporation of a coating material using a thermally heated resistance evaporator or an electron-beam evaporator (9).

23. A method according to any of the above claims, characterized in that the substrate (1) is treated in a first step
on its front (5) with a plasma beam or ion beam, and/or
at least one functional layer (2, 3) is applied, and
the temporary protective layer (4) is applied,
and in a second step
on its back (6) with a plasma beam or ion beam, and/or
at least one functional layer (2, 3) and/or
a temporary protective layer (4) is applied.

24. A method according to claim 23, characterized in that the substrate (1) is turned over between the first and the second step inside a vacuum chamber.

25. A coated substrate at least comprising one functional layer (2, 3) and a temporary protective layer (4) applied to the functional layer (2, 3), characterized in that the temporary protective layer (4) comprises a salt or a salt-like compound that are easily soluble in water or in a polar or protic organic solvent.

26. A coated substrate according to claim 25, characterized in that the temporary protective layer (4) comprises an alkali metal halide.

27. A coated substrate according to claim 26, characterized in that the temporary protective layer (4) comprises a salt-like alkali metal halide, more particularly sodium chloride.

28. A coated substrate according to claim 25, characterized in that the temporary protective layer (4) comprises a salt of an inorganic acid.

29. A coated substrate according to claim 28, characterized in that the temporary protective layer (4) comprises a nitrite or nitrate having at least one metal of the first, second, or third main group (Li, Na, K, Rb, Cs, Fr, Be, Mg, Ca, Sr, Ba, Ra, B, Al, Sc, Y, La) or of the third subgroup (Ga, In, Tl) or comprising a lantanoid.

30. A coated substrate according to claim 28, characterized in that the temporary protective layer (4) comprises a sulfate having at least one metal of the third main group or subgroup (B, Al, Sc, Y, La, Ga, In, Tl).

31. A coated substrate according to claim 28, characterized in that the temporary protective layer (4) comprises a sulfide having at least one metal of the first main group (Li, Na, K, Rb, Cs, Fr).

32. A coated substrate according to claim 28, characterized in that the temporary protective layer (4) comprises a salt-like azide having at least one metal of the first or second main group (Li, Na, K, Rb, Cs, Fr, Be, Mg, Ca, Sr, Ba, Ra).

33. A coated substrate according to claim 28, characterized in that the temporary protective layer (4) comprises a salt-like (iso)cyanide, (iso)cyanate, (iso)fulminate or (iso)thiocyanate.

34. A coated substrate according to claim 25, characterized in that the temporary protective layer (4) comprises a salt-like compound having an alkali metal oxide.

35. A coated substrate according to claim 25, characterized in that the temporary protective layer (4) comprises an organic or carbon-comprising alkali metal oxide compound.

36. A coated substrate according to claim 35, characterized in that the temporary protective layer (4) comprises an organic or carbon-comprising alkali oxide, alkali sulfide, alkali sulfoxide, alkali nitrite, or alkali nitrate.

37. A coated substrate according to any of the above claims 25 through 26, characterized in that the temporary protective layer (4) has a thickness of 5 nm to 100 nm, more particularly 10 nm.

38. A coated substrate according to any of the above claims 25 through 37, characterized in that a first functional layer (2) comprises at least one metal or at least one metal compound.

39. A coated substrate according to any of the above claims 25 through 38, characterized in that the first functional layer (2) comprises a multilayer coating of different metals or metal compounds.

40. A coated substrate according to any of the above claims 25 through 39, characterized in that, to the substrate (1) or to the first the functional layer (2), a second, hydrophobic and/or oleophobic functional layer (3) is applied.

41. A coated substrate according to claim 40, characterized in that, to the substrate (1) or to the first functional layer (2), a second, hydrophobic and/or oleophobic functional layer (3) comprising at least one silicon-organic compound having at least partially perfluorinated carbon atoms or carbon chains is applied.

42. A coated substrate according to any of the above claims 25 through 41, characterized in that the substrate (1) has on its front (5) at least one functional layer (2, 3) and a temporary protective layer (4) and in [sic] on its back (6) at least one functional layer (2, 3) and/or a temporary protective layer (4).

43. A coated substrate according to any of the above claims 25 through 42, characterized in that the substrate (1) comprises a transparent material.

44. A coated substrate according to claim 43, characterized in that the substrate (1) comprises a glass or a plastic.
